(19) United States
(12) Patent Application Publication
(10) Pub. No.: US 2025/0261419 A1
(43) Pub. Date: Aug. 14, 2025

(54) POWER SEMICONDUCTOR DEVICE AND METHOD OF FABRICATING THE SAME

(71) Applicant: SAMSUNG ELECTRONICS CO., LTD., Suwon-si (KR)

(72) Inventors: Mingu Ko, Suwon-si (KR); Youngcheol Kim, Suwon-si (KR); Jongseob Kim, Suwon-si (KR); Taehun Kim, Suwon-si (KR); Jeongin Noh, Suwon-si (KR); Gyeongseon Park, Suwon-si (KR); Seongjo Hong, Suwon-si (KR)

(21) Appl. No.: 19/000,021

(22) Filed: Dec. 23, 2024

(30) Foreign Application Priority Data
Feb. 8, 2024 (KR) 10-2024-0019952

(51) Int. Cl. H10D 62/13; H10D 30/01; H10D 30/66; H10D 62/832

(52) U.S. Cl. CPC H10D 62/155; H10D 30/668; H10D 62/8325; H10D 30/0297

(57) ABSTRACT

A power semiconductor device includes a drift layer of a first conductivity-type on a first conductivity-type substrate, a plurality of well regions of a second conductivity-type on the drift layer, a plurality of source regions of a first conductivity-type respectively disposed on the plurality of well regions, the plurality of well regions and the plurality of source regions comprise stacks having rounded sides, a gate electrode surrounding the stacks and filled a space between the stacks, a gate insulating layer between the stacks and the gate electrode, an interlayer insulating layer on the gate electrode, a source electrode on the interlayer insulating layer and having a plurality of contact portions extending from upper surfaces of the plurality of source regions to the plurality of well regions, and a drain electrode on the bottom of the substrate.

### CROSS-REFERENCE TO RELATED APPLICATION(S)

This application claims priority to Korean Patent Application No. 10-2024-0019952 filed in the Korean Intellectual Property Office on Feb. 8, 2024, the entire disclosure of which is incorporated herein by reference.

### BACKGROUND

Power semiconductor devices are semiconductor devices operating in high voltage and high current environments and are used in fields requiring high power switching, such as power conversion, power converters, inverters, and the like. Power semiconductor devices basically require withstand voltage characteristics against high voltages, and recently, additionally require high-speed switching operations. Accordingly, research into power semiconductor devices using SiC having superior voltage resistance characteristics compared to silicon (Si) is being undertaken.

### SUMMARY

In general, in some aspects, the present disclosure is directed toward power semiconductor devices having improved electrical characteristics and methods of fabricating power semiconductor devices having improved electrical characteristics.

According to some implementations, the present disclosure is directed to a power semiconductor device that includes a substrate of a first conductivity-type; a drift layer of the first conductivity-type on the substrate; a plurality of well regions of a second conductivity-type disposed on the drift layer and arranged at a regular interval in plan view; a plurality of source regions of the first conductivity-type respectively disposed on the plurality of well regions, each of the stacks of the plurality of well regions and the plurality of source regions having rounded sides; a gate electrode surrounding the stacks and filled a space between the stacks; a gate insulating layer disposed between the stacks and the gate electrode; an interlayer insulating layer on the gate electrode; a source electrode disposed on the interlayer insulating layer and having a plurality of contact portions respectively extending from upper surfaces of the plurality of source regions to the plurality of well regions; and a drain electrode on the bottom of the substrate.

According to some implementations, the present disclosure is directed to a power semiconductor device that includes a substrate of a first conductivity-type; a drift layer of the first conductivity-type on the substrate; a plurality of well regions of a second conductivity-type are disposed on the drift layer and arranged at a regular interval in plan view, the plurality of well regions including first well regions and second well regions; first source regions of the first conductivity-type respectively disposed on the first well regions, each of the first stacks of the first well regions and the first source regions having a rounded side surface; second source regions of the second conductivity-type respectively disposed on the second well regions, each of the second stacks of the second well regions and the second source regions having a rounded side surface; a gate electrode surrounding each of the first and second stacks and filling a space between the first and second stacks; a gate insulating layer disposed between the first stacks and the gate electrode; an interlayer insulating layer on the gate electrode; a source electrode disposed on the interlayer insulating layer and connected to the second source regions; and a drain electrode on the bottom of the substrate.

According to some implementations, the present disclosure is directed to a power semiconductor device that includes a substrate of a first conductivity-type; a drift layer of the first conductivity-type on the substrate; a plurality of well regions of a second conductivity-type disposed on the drift layer and arranged in a hexagonal shape in plan view; a plurality of source regions of the first conductivity-type respectively disposed on the plurality of well regions, each of the stacks of the plurality of well regions and the plurality of source regions having a cylindrical structure; gate electrodes filled in the trenches defining the stacks; a gate insulating layer disposed between the stacks and the gate electrode and surrounding the stacks; an interlayer insulating layer on the gate electrode; a source electrode disposed on the interlayer insulating layer and having a plurality of contact portions extending from upper surfaces of the plurality of source regions to the plurality of well regions; and a drain electrode on the bottom of the substrate.

According to some implementations, the present disclosure is directed to a method of manufacturing a power semiconductor device that includes forming a substrate structure in which a drift layer of a first conductivity-type, a well layer of a second conductivity-type, and a source layer of the first conductivity-type are sequentially disposed on a substrate of the first conductivity-type; forming a plurality of pillar-shaped stacks each having a well region of the second conductivity-type and a source region of the first conductivity-type by patterning the well layer and the source layer to a depth up to a partial region of the drift layer; forming a gate insulating layer on the exposed surface of the drift layer and sidewalls of the plurality of pillar-shaped stacks; forming a gate electrode surrounding the plurality of pillar-shaped stacks on the gate insulating layer; forming an interlayer insulating layer on the gate electrode; forming a source electrode connected to a source region of each of the plurality of pillar-shaped stacks on the interlayer insulating layer; and forming a drain electrode on a lower surface of the substrate.

### BRIEF DESCRIPTION OF DRAWINGS

Example implementations will be more clearly understood from the following detailed description, taken in conjunction with the accompanying drawings.

FIG. 1 is a schematic perspective view illustrating an example of a power semiconductor device according to some implementations.

FIG. 2 is a plan view illustrating an example of a partial area (A) of the power semiconductor device illustrated in FIG. 1 according to some implementations.

FIG. 3 is a side cross-sectional view of the power semiconductor device illustrated in FIG. 2, taken along line II-II′ according to some implementations.

FIG. 4 is a partial enlarged view illustrating an example of a partial area (B) of the power semiconductor device illustrated in FIG. 3 according to some implementations.

FIGS. 5 and 6 are a plan view and a side cross-sectional view, respectively, illustrating an example of a power semiconductor device according to some implementations.

FIGS. 7A and 7B are plan views illustrating examples of arrangements of power semiconductor devices according to comparative examples and some implementations.

FIG. 8 is a graph illustrating examples of a gate area ratio and a channel width according to a diameter of a stack (well and source regions) according to some implementations.

FIGS. 9 and 10 are a plan view and a side cross-sectional view, respectively, illustrating an example of a power semiconductor device according to some implementations.

FIGS. 11A and 11B are plan views illustrating examples of a power semiconductor devices according to some implementations.

FIGS. 12A to 12H are cross-sectional views showing examples of main processes to describe an example of a method of manufacturing a power semiconductor device according to some implementations.

FIGS. 13A to 13G are cross-sectional views for examples of main processes of an example of a method of manufacturing a power semiconductor device according to some implementations.

### DETAILED DESCRIPTION

Hereinafter, example implementations will be explained in detail with reference to the accompanying drawings.

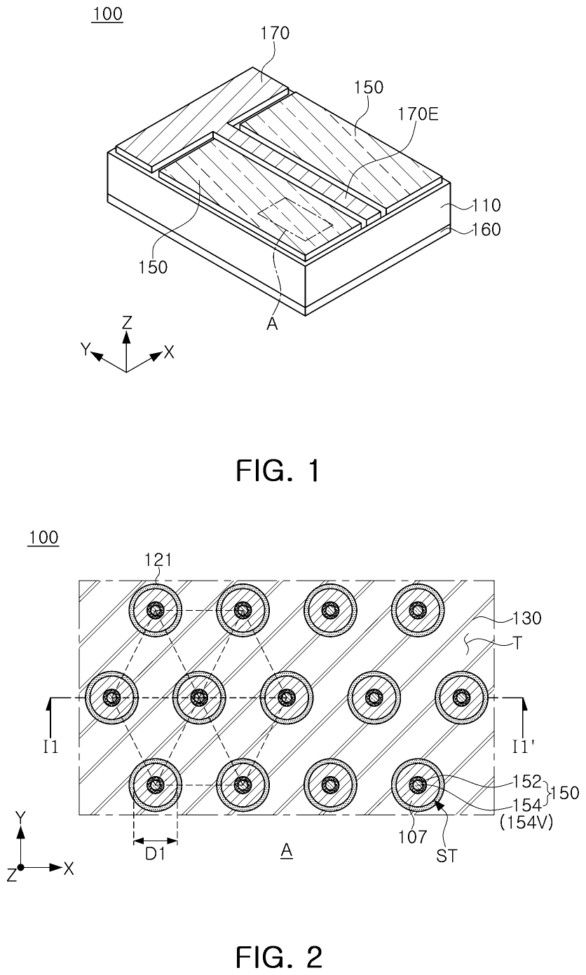

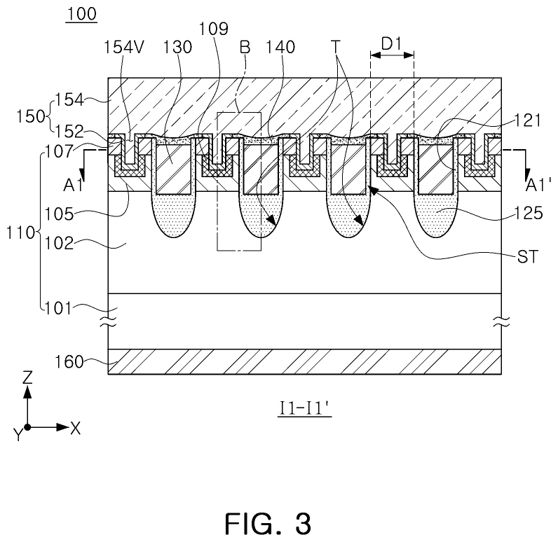

FIG. 1 is a schematic perspective view illustrating an example of a power semiconductor device according to some implementations, and FIGS. 2 and 3 are top and side views illustrating an example of a partial area (A) of the power semiconductor device illustrated in FIG. 1 according to some implementations. In particular, FIG. 2 is a plan cross-sectional view of the power semiconductor device illustrated in FIG. 3 taken along line A1-A1′, and FIG. 3 is a side cross-sectional view of the power semiconductor device illustrated in FIG. 2 taken along line II-II′.

In FIGS. 1 and 2, a power semiconductor device 100 may include a substrate 101 of a first conductivity-type, a drift layer 102 of a first conductivity-type on a substrate 101 of a first conductivity-type, a plurality of well regions 105 on a drift layer 102 of a first conductivity-type, and a plurality of source regions 107 respectively disposed on the plurality of well regions 105. In this case, the substrate 101, the drift layer 102, the well regions 105, and the source regions 107 may be understood as the substrate structure 110 of FIG. 1.

In addition, the power semiconductor device 100 may further include a drain electrode 160 disposed on the lower surface of the first conductive substrate 101, and a source electrode 150 and a gate electrode pad 170 disposed on the upper surface of the power semiconductor device 100. The source electrode 150 may be connected to the source regions 107, and the gate electrode pad 170 may be connected to the gate electrode 130. In some implementations, the source electrode 150 is divided into two, and the gate electrode pad 170 may have an electrode portion 170E extending between the two source electrodes 150, but the present disclosure is not limited thereto, and the electrode arrangement may be changed in various manners.

The substrate 101 may be provided as a bulk wafer or an epitaxial layer. The substrate 101 may include a semiconductor material, for example, SiC. However, in some implementations, the substrate 101 may include a group IV semiconductor material, such as Si or Ge, or a compound semiconductor material, such as SiGe, GaAs, InAs, or InP. The substrate 101 may include first conductivity-type impurities and may have a first conductivity-type. In some implementations, the first conductivity-type may be, for example, N-type, and the first conductivity-type impurities may be N-type impurities, for example, nitrogen (N) and/or phosphorus (P). In some implementations, the first conductivity-type may be, for example, P-type, and the first conductivity-type impurities may be, for example, P-type impurities, such as aluminum (Al).

The drift layer 102 may be disposed on substrate 101. Drift layer 102 may include SiC, for example. The drift layer 102 may be an epitaxial layer grown on the substrate 101. The drift layer 102 may include impurities of a first conductivity-type and thus may have the first conductivity-type. The concentration of first conductivity-type impurities in the drift layer 102 may be lower than the concentration of first conductivity-type impurities in the substrate 101. In some implementations, the first conductivity-type impurities in the substrate 101 and the drift layer 102 may include the same or different elements.

The plurality of well regions 105 may be arranged at a predetermined depth from the top surface of the drift layer 102. The plurality of well regions 105 may include a semiconductor material, for example, SiC. The plurality of well regions 105 may be regions in which second conductivity-type impurities are ion-implanted into the upper region of the drift layer 102. For example, the second conductivity-type may be P-type, and the second conductivity-type impurities may be P-type impurities, such as aluminum (Al). In some implementations, each of the plurality of well regions 105 may include a plurality of regions with different doping concentrations.

The plurality of source regions 107 may be disposed at a predetermined thickness from the upper surfaces of each well region 105. The thickness of the plurality of source regions 107 is smaller than the thickness of the well region 105. Source regions 107 may include SiC, for example. The source regions 107 may be regions in which first conductivity-type impurities are ion-implanted into the upper regions of the well regions 105. The first conductivity-type may be, for example, N-type, and may include the first conductivity-type impurities described above. The concentration of first conductivity-type impurities in the source region 107 may be higher than the concentration of first conductivity-type impurities in the drift layer 102, but is not limited thereto.

The power semiconductor device 100 may include a plurality of well contact regions 109 disposed between the well region 105 and the source electrode 150. Voltage from the source electrode 150 may be applied to the well region 105 through the well contact regions 109. In some implementations, the well contact regions 109 may have a structure surrounding a portion of the source electrode 150 extending within the well regions 105, for example, the contact via 154V. The structure of the well contact regions 109 is not limited thereto, and in some implementations, may be formed to surround the side of the contact via 154V of the source electrode 150 (see FIG. 6) or to contact another part of the contact via. The well contact region 109 may include a semiconductor material, for example, SiC. The well contact region 109 may be a region having the second conductivity-type, and may include the second conductivity-type impurities described above. The concentration of second conductivity-type impurities in the well contact region 109 may be higher than the concentration of second conductivity-type impurities in the well region 105.

In some implementations, stacks ST (also referred to as “cells”) of each of the plurality of well regions 105 and the plurality of source regions 107 has a pillar structure with rounded sides.

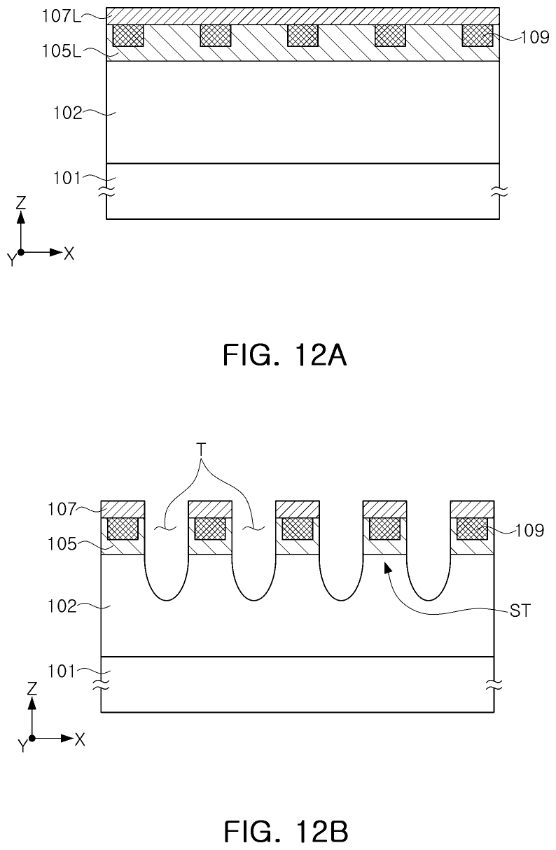

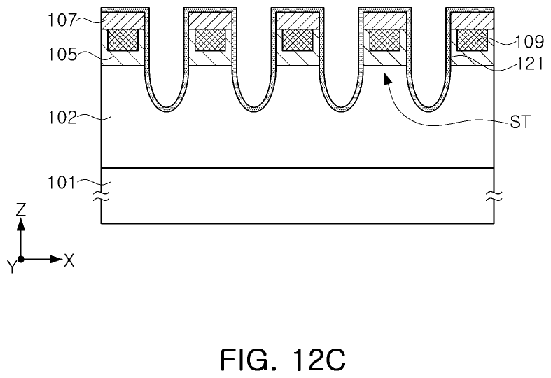

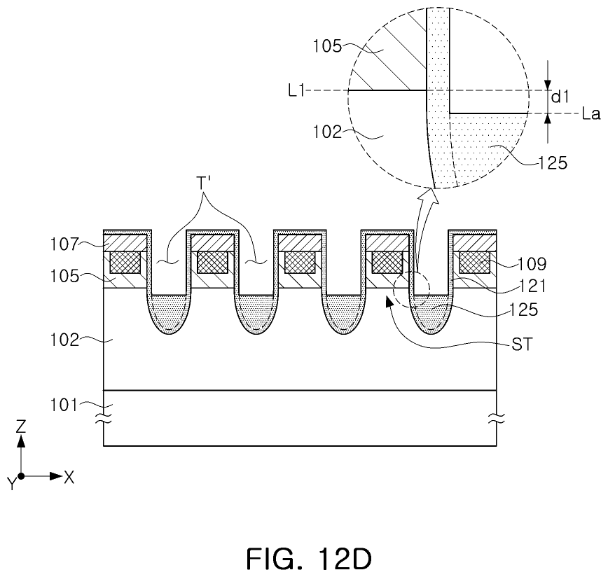

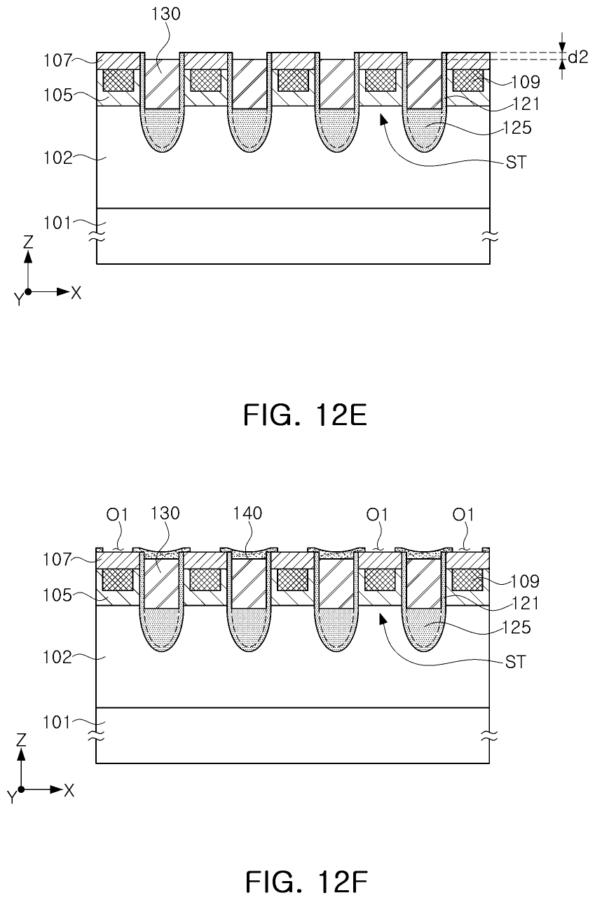

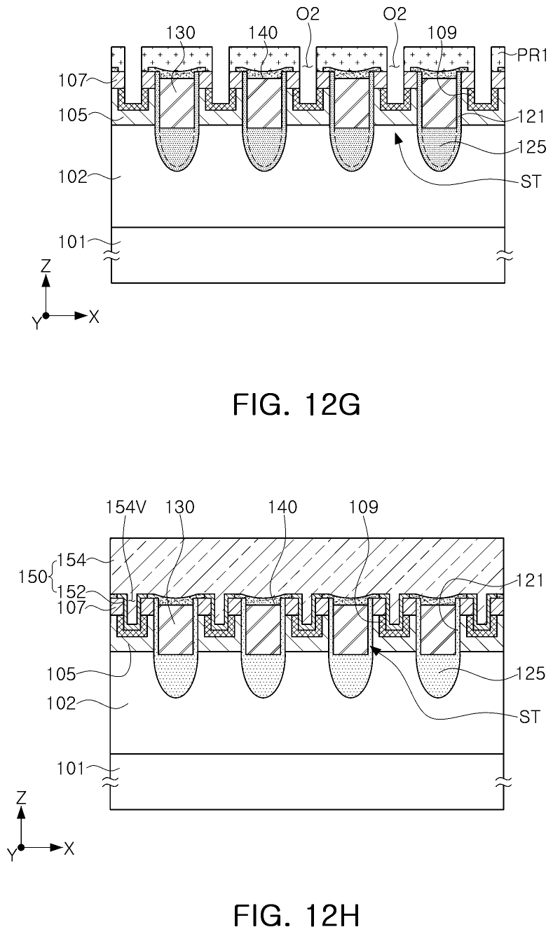

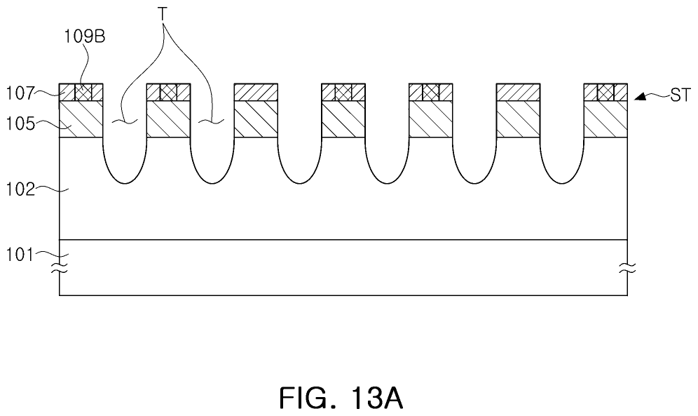

In FIG. 2, from a plan view, each of the stacks ST may have a circular pillar structure with a circular cross-section. The cylindrical stacks (ST) may be arranged in a hexagonal shape at regular intervals. As illustrated in FIG. 3, the stacks ST employed in this embodiment may include an upper region of the drift layer 102. These stacks (ST) have a layer structure through an ion implantation process in the drift layer 102, and may be obtained by etching the second conductivity-type well layer 105L and the first conductivity-type source layer 107L up to a partial area of the drift layer 102 (see FIG. 12b) after forming the well layer 105L of the second conductivity-type and the source layer 107L of the first conductivity-type (see FIG. 12A).

The power semiconductor device 100 may further include a gate electrode 130 surrounding the stacks ST and filled between the stacks ST, and a gate insulating layer 121 disposed between the stacks ST and the gate electrode 130.

As previously described, a plurality of stacks ST may be obtained by patterning the layer structure (see FIGS. 12A and 12B). As a result, the trench area T may be defined by a plurality of stacks ST each having a circular pillar structure arranged in a hexagonal shape, as illustrated in FIG. 2. This trench region T may have a depth extending from the top surfaces of the source regions 107, past the source regions 107 and the well regions 105 to a portion of the drift layer 102. In this manner, the trench region T may completely penetrate the well region 105, and the bottom of the trench region T may be provided by the drift layer 102. The trench area T provides a space where the gate structure, for example, the gate insulating layer 120 and the gate electrode 130, are disposed.

As previously described, the gate electrode 130 may be disposed in the trench region T to surround the plurality of stacks ST, as illustrated in FIG. 2. The gate insulating layer 121 may be disposed between the stacks ST and the gate electrode 130.

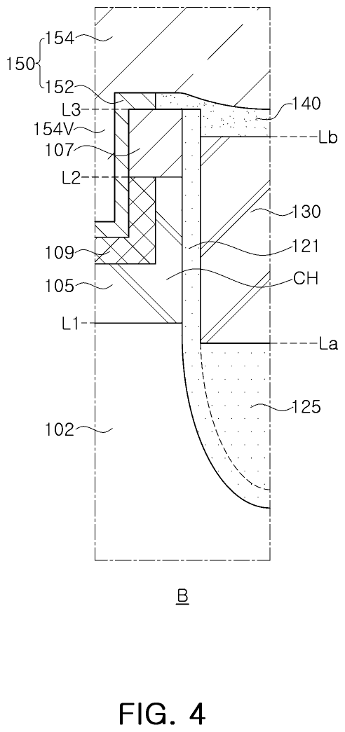

The gate electrode 130 may overlap the well region 105 at least in the horizontal direction (for example, X- or Y-direction). In some implementations, the gate electrode 130 may overlap a portion of the drift region and a portion of the source region 107 in the horizontal direction. FIG. 4 is a partial enlarged view illustrating part B of the power semiconductor device illustrated in FIG. 3.

In FIGS. 3 and 4, the lower surface of the gate electrode 130 may be located at a level (La) lower than the lower surface level (L1) of the well regions 105. Meanwhile, the top surface of the gate electrode 130 may be located at a level (Lb) higher than the top surface level (L2) of the well regions 105. Additionally, the top surface of the gate electrode 130 may be located at a level (Lb) lower than the top surface level (L3) of the source region 107.

In some implementations, the plurality of stacks ST has a cylindrical structure, as described above, and the gate electrode 130 and the gate insulating layer 121 are disposed surrounding the side surfaces, and not only may a crystal plane with excellent mobility be used as a channel region (CH), but also a channel region (CH) with a gate all around structure surrounding the side of the well region 105 may be provided. As a result, the power semiconductor device 100 may secure a large channel area with improved electrical characteristics. Additionally, since the source region 107 of the plurality of stacks ST has an overall rounded side surface without any angled portions, problems caused by current concentration may be solved. In some implementations, the plurality of stacks ST are illustrated as pillar structures having a circular cross-section in the horizontal direction (X-Y-direction), but may also include various other pillar structures having rounded side surfaces. For example, the plurality of stacks ST may include a pillar structure with a side surface where each corner portion is rounded, even if the overall cross-section is polygonal (for example, square, regular hexagon, etc.).

The gate electrode 130 may include a conductive material, for example, semiconductor materials, such as doped polycrystalline silicon, metal nitride, such as titanium nitride (TiN), tantalum nitride (TaN), or tungsten nitride (WN), and/or metallic substances, such as aluminum (Al), tungsten (W), or molybdenum (Mo). In some embodiments, the gate electrode 130 may be composed of two or more multiple layers.

In FIG. 4, during operation of the power semiconductor device 100, a channel region (CH) of the transistor may be formed in a region of the plurality of well regions 105 adjacent to the gate electrode 130 and facing the gate electrode 130. The channel region CH may include the side of the well regions 105 or may be an area adjacent to the side of the well regions 105. The channel region CH may face the gate electrode 130 with the gate insulating layer 121 interposed therebetween. The channel region CH is a partial region of the well region 105 and may extend downward from the source region 107 along the side of the gate insulating layer 121. As described above, the channel region CH may horizontally overlap the gate electrode 130.

In FIG. 3, the gate insulating layer 121 may extend along the inner surface of the trench region T. For example, the gate insulating layer 121 may extend to the bottom of the trench region T. In this manner, the gate insulating layer 121 may be disposed between the source region 107, the well region 105, and the drift layer 102 and the gate electrode 130. The bottom insulating portion 125 may be disposed on the gate insulating layer 121 at the bottom of the trench region T. The bottom insulating portion 125 may have a thickness greater than the thickness of the gate insulating layer 121. A bottom insulating portion 125 having a relatively large thickness is disposed at the bottom of the trench region T, and accordingly, destruction of the gate insulating layer 121 and the bottom insulating portion 125 due to the electric field formed in the drift layer 102 may be prevented. The bottom level (La) of the gate electrode 130 may be defined by the top surface level of the bottom insulating portion 125.

For example, the gate insulating layer 121 may include oxide, nitride, or a high-k material. The high dielectric constant material may refer to a dielectric material having a higher dielectric constant than a silicon oxide film (SiO2). The high dielectric constant material may refer to a dielectric material having a higher dielectric constant than a silicon oxide film (SiO2). The high dielectric constant material may include any one of, for example, aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), and hafnium silicon oxide. (HfSixOy), lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3). The bottom insulating portion 125 may include the same material as the gate insulating layer 121. For example, the bottom insulating portion 125 may include oxide or nitride. Although the bottom insulating portion 125 has been described as having a separate structure from the gate insulating layer 121, in some implementations, the bottom insulating portion 125 may be described as an insulating structure included in the gate insulating layer 121. In detail, in this insulating structure, it may be understood that the thickness of the gate insulating layer 121 in the vertical direction (Z-direction) at the bottom of the gate electrode 130 is greater than the thickness of the gate insulating layer 121 in the horizontal direction (X-direction or Y-direction) on the side of the gate electrode 130.

The power semiconductor device 100 further includes an interlayer insulating layer 140 on the gate electrode 130. The interlayer insulating layer 140 may cover the gate electrodes 130 and may be disposed to expose a portion of each of the source regions 107. The interlayer insulating layer 140 may fill the trench region T and cover the top surface of the gate electrode 130 and the top surface of the gate insulating layer 121. The interlayer insulating layer 140 may include an insulating material and may include at least one of silicon oxide, silicon nitride, and silicon oxynitride.

In FIGS. 2 and 3, the source electrode 150 may include an electrode layer disposed on the interlayer insulating layer 140 and electrically connected to the source regions 107. The contact vias 154V employed in this embodiment are disposed in a substantially central area of the stacks ST rather than the plurality of well areas 105, respectively. Accordingly, the contact vias 154V may increase the contact area with the source region 107.

In some implementations, the electrode layer 154 may have a plurality of contact vias 154V extending from the top surface of the plurality of source regions 107 to the plurality of well regions 105. The contact vias 154V employed in this embodiment may be formed deeper than the plurality of source regions 107. In this manner, the source electrode 150 may be connected not only to the plurality of source regions 107 but also to the plurality of well regions 105 through the plurality of contact vias 154V.

In some implementations, the source electrode 150 may reduce contact resistance by increasing the area in contact with the second conductivity-type well region 105 through the contact vias 154V. As a result, the contact area through which diode current may flow when a reverse voltage is applied may be increased. In this manner, the power semiconductor device 100 may improve ruggedness current capability (Ruggedness). Additionally, the on-resistance between the drain electrode 160 and the source electrode 150 may be lowered through the contact vias 154V.

The source electrode 150 may further include a plurality of metal-semiconductor compound layers 152. The plurality of metal-semiconductor compound layers 152 may respectively extend from the top surface of the plurality of source regions 107 along the side surfaces of the plurality of well regions 105 and surround the contact vias 154V. The electrode layer 154 may include a metal material, for example, at least one of nickel (Ni), aluminum (Al), titanium (Ti), silver (Ag), vanadium (V), tungsten (W), cobalt (Co), and molybdenum (Mo), as well as copper (Cu), and ruthenium (Ru). The plurality of metal-semiconductor compound layers 152 may include a metal element and a semiconductor element, for example, at least one of TiSi, CoSi, MoSi, LaSi, NiSi, TaSi, or Wsi.

The drain electrode 160 may be disposed on the lower surface of the substrate 101 and electrically connected to the substrate 101. The drain electrode 160 may include at least one of a metal material, for example, nickel (Ni), aluminum (Al), titanium (Ti), silver (Ag), vanadium (V), and tungsten (W). In some implementations, the drain electrode 160 may also include a metal-semiconductor compound layer and an electrode layer similar to the source electrode 150.

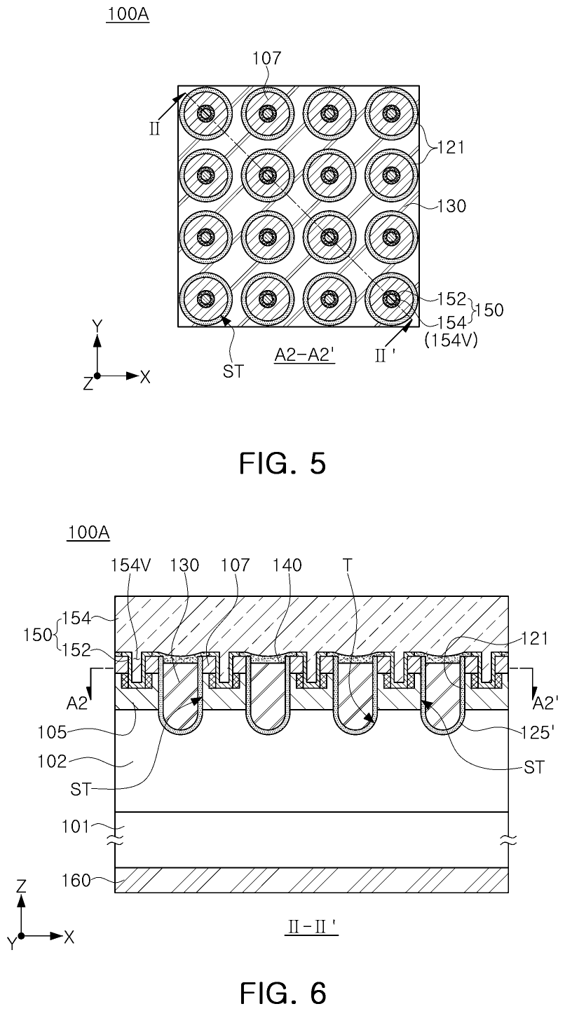

FIGS. 5 and 6 are a plan view and a side cross-sectional view, respectively, illustrating an example of a power semiconductor device according to some implementations. In this case, FIG. 5 is a plan view of the power semiconductor device illustrated in FIG. 6 taken along line A2-A2′, and FIG. 6 is a side cross-sectional view of the power semiconductor device illustrated in FIG. 5 taken along line II-II′.

In FIGS. 5 and 6, the power semiconductor device 100A may be understood as similar to the power semiconductor device 100 illustrated in FIGS. 1 and 2 to 4, except that the stacks ST are arranged in a square shape, a relatively thin bottom insulating portion 125′ is included, and the well contact area 109A is located on the side of the contact via 154V. Additionally, unless otherwise stated, the components of some implementations may be understood with reference to the description of the same or similar components of the power semiconductor device 100 illustrated in FIGS. 1 and 2 to 4.

The stacks ST include a circular pillar structure similar to some implementations, but may be arranged differently from some implementations from a plan view. The stacks (ST) may be arranged in an almost square shape.

The bottom insulating portion 125′ may have a thinner thickness than the bottom insulating portion 125 of some implementations. The bottom insulating portion employed in some implementations may have a substantially constant thickness with the gate insulating layer 121. In some implementations, the gate insulating layer 121 may extend conformally along the inner surface of the trench region T, and the bottom of the trench region T, for example, a portion located in the region of the drift layer 102, may be provided as the bottom insulating portion 125′.

In some implementations, the well contact area 109A may be formed to surround only the portion where the source electrode 150 extends into the well area 105, for example, the side of the contact via 154V.

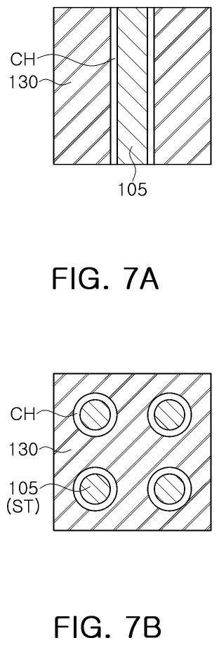

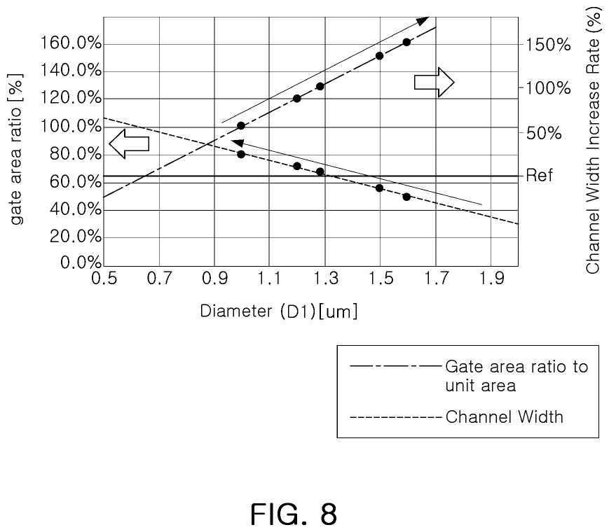

FIGS. 7A and 7B are plan views illustrating examples of arrangements that may be introduced into power semiconductor devices according to comparative examples and some implementations, and FIG. 8 is a graph illustrating an example of a gate area ratio and a channel width according to the diameter of the stack (well and source regions) in the arrangement of FIG. 7B according to some implementations.

In FIGS. 7A and 7B, for the arrangement of power semiconductor devices, according to comparative examples and some implementations, a stripe pattern (comparative example) and a circular stack arrangement (example) are illustrated, respectively, within the same unit area (4 μm×4 μm).

In detail, in the comparative example illustrated in FIG. 7A, within a unit area (4 μm×4 μm), the well region 105 (corresponding to the stack) and the gate electrode 130 each extend in one direction and have a stripe structure arranged alternately. FIG. 7A shows the well region 105, the gate electrode 130, and a channel (CH) formed in the area adjacent to the gate electrode 130 in the well region 105, and for convenience of explanation, other structures such as the gate insulating layer have been omitted. In this case, the width of the well region 105 in the X-direction is 1.3 μm, and the width of each of the two gate electrodes 130 in the X-direction is 1.35 μm. Within a unit area, the Y-direction width (or channel width) of the channel (CH) is 4 μm, and the total channel width is 8 μm.

In FIG. 7B, while forming the same number of stacks within the same unit area (4 μm×4 μm), the diameter (see ‘D1’ in FIG. 2) of the stack (“ST” in FIG. 7B) was implemented differently as illustrated in Table 1 (A1 to A5) below. In FIG. 7B, similar to FIG. 7a, the well region 105, the gate electrode 130, and the channel (CH) formed in the area adjacent to the gate electrode 130 in the well region 105 are illustrated, and for convenience of explanation, other structures such as the gate insulating layer have been omitted.

FIG. 8 and Table 1 below show simulation results of the planar area ratio and channel width of the gate electrode 130 in each comparative example (Ref.) and examples (A1 to A5). In implementations A1 to A5, the channel CH is formed along the outer edge of the well region 105, so the channel width may correspond to the circumferential length of the well region 105. Since four stacks (ST) are formed within a unit area, the total channel width is four times the circumferential length of each well region 105.

TABLE 1

| | | Stack | Gate Plane | Ratio of | Channel | |
|---|---|---|---|---|---|---|
| | Number | Diameter | Area | gate area to | Width | Increase |
| Division | of Stacks | (μm) | (μm²) | unit area | (μm) | Rate |
| Comparative | — | — | 10.8 | 67.5% | 8 | — |
| Example (Ref) | | | | | | |
| A1 | 4 | 1.0 | 12.86 | 80.4% | 12.6 | 57% |
| A2 | 4 | 1.2 | 11.48 | 71.7% | 15.1 | 88% |
| A3 | 4 | 1.3 | 10.80 | 67.5% | 16.2 | 102% |
| A4 | 4 | 1.5 | 8.93 | 55.8% | 18.8 | 136% |
| A5 | 4 | 1.6 | 7.96 | 49.7% | 20.1 | 151% |

Referring to Table 1 along with FIG. 8, the power semiconductor devices according to some implementations may have a channel width increased by at least 50% or more compared to the comparative example. In particular, it can be seen that the channel width of the power semiconductor devices is increased by almost two times even under the condition (A3) with the same gate electrode planar area (67.5%) as that of the comparative example.

In some implementations, the width of the channel CH is defined by a circular channel region between the gate electrode 130 and the well region 105, as illustrated in FIG. 7B, and even when it is implemented in a size (diameter or spacing of the stack) similar to the size (widths of stripes) of the comparative example, since four may be arranged, the channel width may be expanded by the number of stacks.

In this manner, the power semiconductor devices adopt a gate all-around structure, and the channel area (or width) may be expanded compared to the channel area (or width) of the comparative example (for example, stripe pattern), and the problem caused by relatively low mobility may be effectively compensated.

Meanwhile, in FIG. 8, in the hexagonal arrangement of the stacks from a planar perspective, the spacing between the stacks may vary from about 1 μm to 0.5 μm in the diameter range of the stacks (1 μm to 1.5 μm). The diameter of each of the stacks may be 0.3 to 1.5 times the spacing between the stacks.

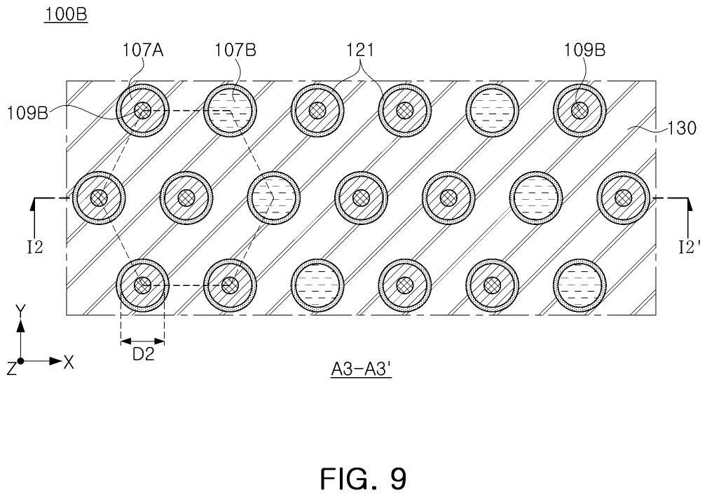

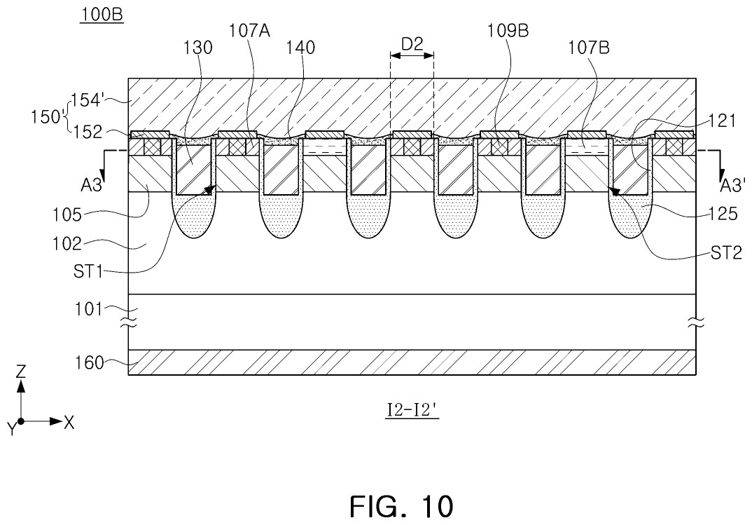

FIGS. 9 and 10 are a plan view and a side cross-sectional view, respectively, illustrating an example of a power semiconductor device according to some implementations. In this case, FIG. 9 is a plan view of the power semiconductor device illustrated in FIG. 10 taken along line A3-A3′, and FIG. 10 is a side cross-sectional view of the power semiconductor device illustrated in FIG. 9 taken along line 12-12′.

In FIGS. 9 and 10, the power semiconductor device 100A may be understood as similar to the power semiconductor device 100 illustrated in FIGS. 1 and 2 to 4, except that the stacks include first and second stacks ST1 and ST2 having source regions 107A and 107B of different conductivity-types and the connection of the source electrode 150′ includes a different point. Additionally, unless otherwise stated, the components of some implementations may be understood with reference to the description of the same or similar components of the power semiconductor device 100 illustrated in FIGS. 1 and 2 to 4.

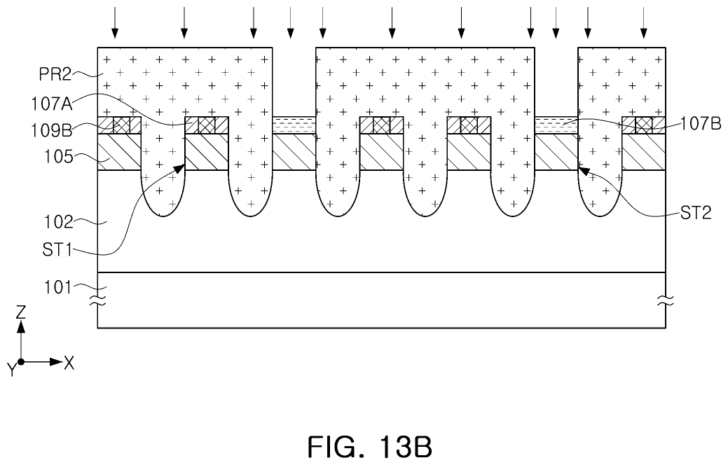

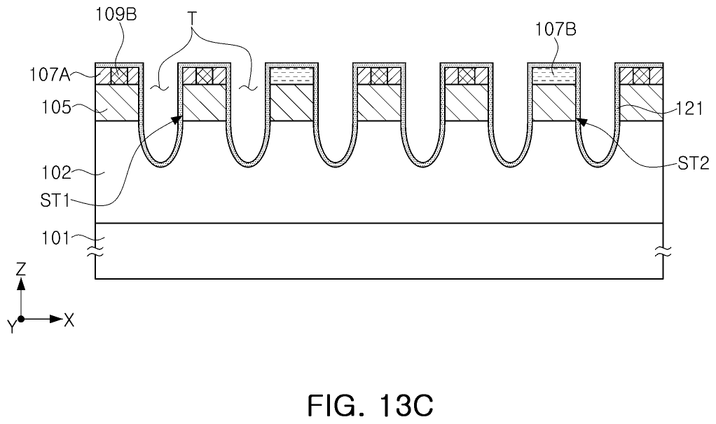

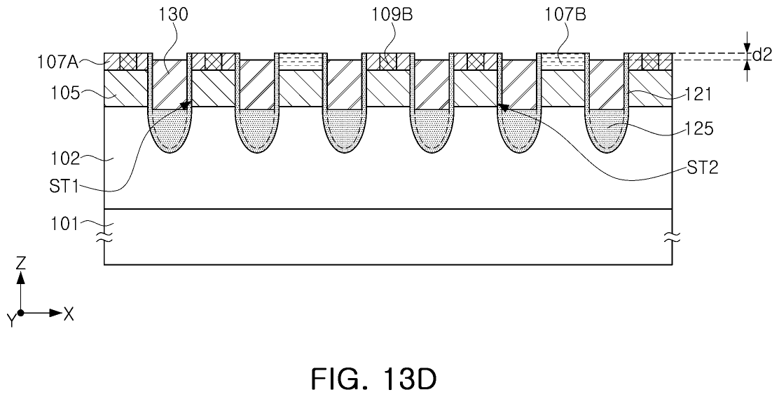

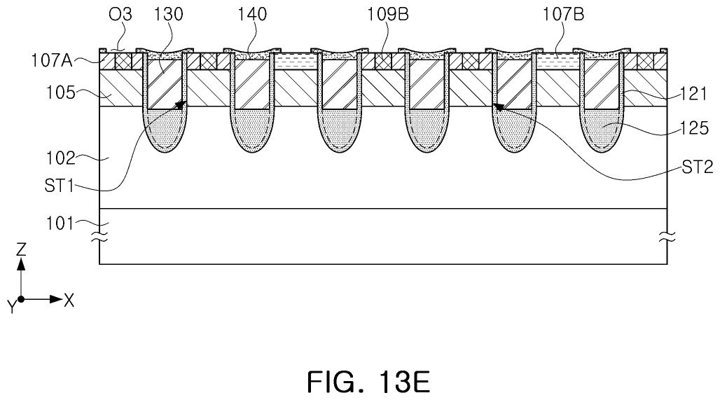

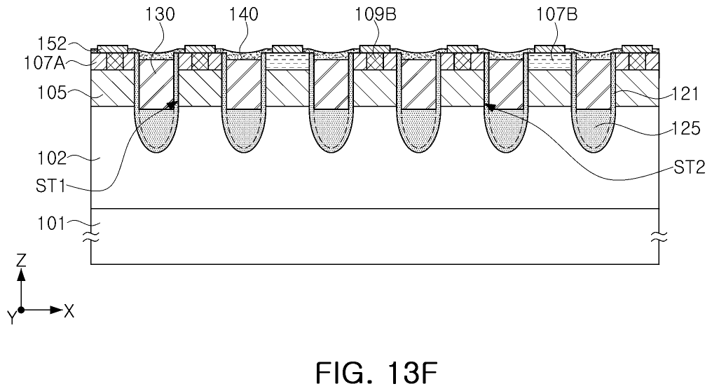

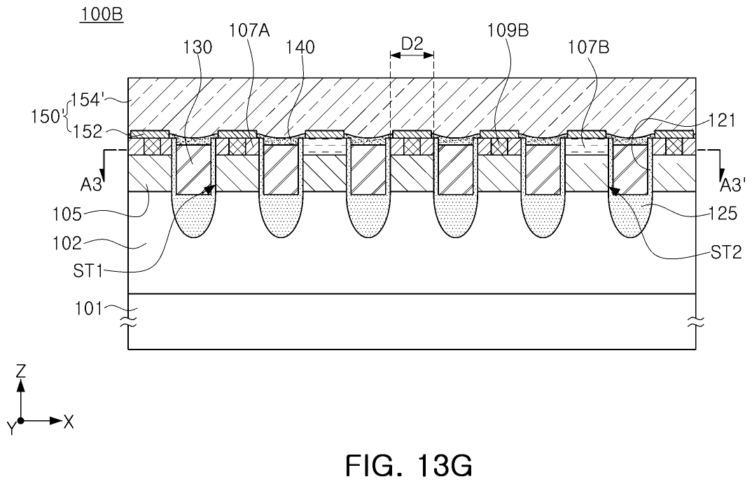

The stacks employed in some implementations may include a cylindrical structure similar to other implementations. The stacks include first and second stacks ST1 and ST2 having source regions 107A and 107B of different conductivity-types. In detail, the first stacks (ST1) may include a first source region 107A of a first conductivity-type, and the second stacks ST2 may include a second source region 107B of a second conductivity-type, similar to the source region 107 constituting the MOSFET cell in some implementations. In some implementations, the second source region 107B may be formed by selectively counter-doping portions of the first source regions 107A of the first conductivity-type (FIG. 13B). In some implementations, the second source region 107B, the well region 105, and the drift layer 120 may function as a P-N diode. Accordingly, the second source region 107B may be referred to as a ‘diode region’. In the second stack ST2, the second source region 107B has the same conductivity-type as the well region 105 and may be doped at a higher concentration than the well region 105.

The source electrode 150′ may include an electrode layer 154′ on the interlayer insulating layer 140, and a plurality of metal-semiconductor compound layers 152 between the electrode layer 154′ and the first and second source regions 107A and 107B, similar to the source electrode 150 of some implementations. However, unlike some implementations, the source electrode 150′ employed does not include a contact via (‘154V’ in FIG. 3), and instead, may be configured to contact the second source region 107B of a different conductivity-type along with the first source region 107A. In this manner, the source electrode 150′ is contacted with the second source region 107B of the second conductivity-type instead of contacting the well region 105 of the second conductivity-type, and when a reverse voltage is applied, an effect similar to the robustness current capability may be expected by widening the area through which the diode current may flow.

The first stacks (ST1) constituting the MOSFET cell may be arranged in greater numbers than the second stacks (ST2) to improve robustness and current capability. In this embodiment, the first stacks ST1 and the second stacks ST2 may be arranged in approximately 2:1 ratio.

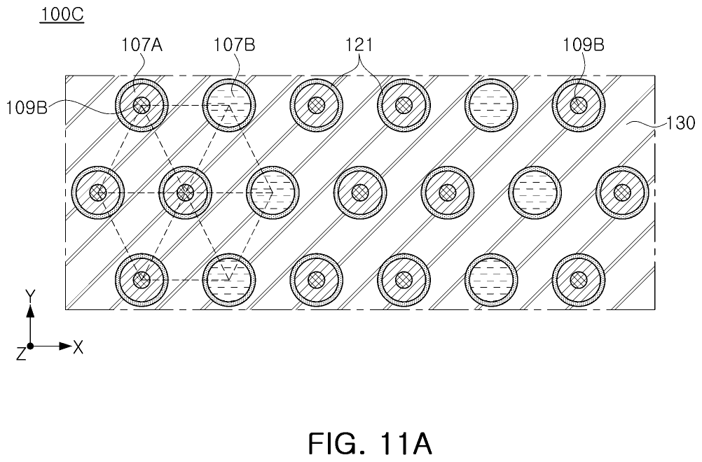

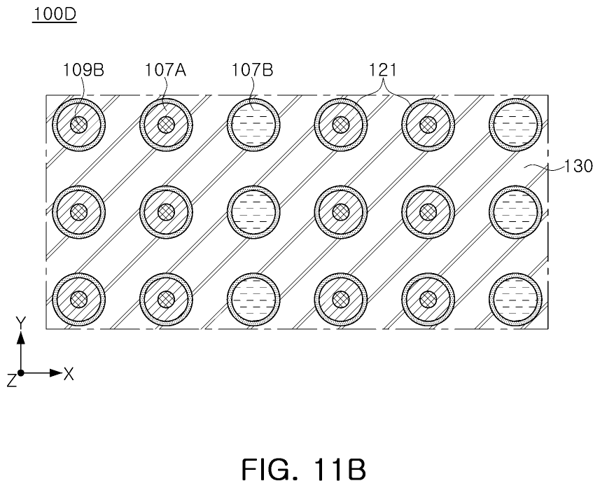

In FIG. 9, from a plan view, between the first stacks ST1 of a pair of lines and the first stacks ST1 of another pair of lines in the diagonal direction. One line of second stacks ST2 may be disposed. The first stacks ST1, each of which is located on both sides of the second stacks ST2 in one direction (for example, X-direction), may be arranged at equal intervals. The arrangement of the first and second stacks ST1 and ST2 may be implemented in various manners (see FIGS. 11A and 11B).

The well contact regions 109B may be provided only to the first stack ST1. In the first stack ST1, well contact regions 109B may be arranged to connect the well region 105 and the source electrode 150 in the first source region 107A. The well contact region 109B may include a semiconductor material, for example, SiC. The well contact region 109B may be a region having the second conductivity-type, and may include the second conductivity-type impurities described above. The concentration of second conductivity-type impurities in the well contact region 109B may be higher than the concentration of second conductivity-type impurities in the well region 105.

The power semiconductor device 100B may be advantageously applied in a smaller structure than the power semiconductor device 100 of some implementations. In detail, when the first stack (ST1) employed in this embodiment has a diameter (D2) smaller than the diameter (D1) of the stack (ST) in some implementations, the process of forming holes for contact vias (see FIG. 12g) may be difficult to implement. In this case, the structure of the source electrode 150′ may be advantageously employed.

FIGS. 11A and 11B are plan views illustrating examples of power semiconductor devices according to some implementations. In FIG. 11A, the power semiconductor device 100C includes first and second stacks ST1 and ST2 arranged in about 2:1, similar to some implementations, and may have arrangement of the first and second stacks (ST1, ST2) different from the previous embodiment from a plan view.

In detail, between the first stacks ST1 of a pair of lines and the first stacks ST1 of another pair of lines, arranged in a zigzag pattern in the Y-direction. One line of second stacks (ST2) arranged in a zigzag pattern in the same direction may be placed. The first stacks ST1, each of which is located on both sides of the second stacks ST2 in one direction (for example, X-direction), may be arranged at equal intervals.

In FIG. 11B, unlike implementations shown in FIGS. 9 and 11A, the power semiconductor device 100D includes first and second stacks arranged in a square shape. In some implementations, the first and second stacks ST1 and ST2 are arranged approximately 2:1.

In detail, between the first stacks ST1 of a pair of lines and the first stacks ST1 of another pair of lines arranged in the Y-direction. One line of second stacks (ST2) arranged in the same direction may be placed. The first stacks ST1, each of which is located on both sides of the second stacks ST2 in one direction (for example, X-direction), may be arranged at equal intervals.

The arrangement that may be implemented in the power semiconductor device is not limited to the arrangement of the first and second stacks ST1 and ST2 described above, and may have a ratio of different numbers of first and second stacks (ST1, ST2). The second stacks ST2 may be arranged in different positions.

FIGS. 12A to 12H are cross-sectional views showing examples of a main processes to describe an example of a method of manufacturing a power semiconductor device according to some implementations. The manufacturing method according may be understood as an example of a method of manufacturing the power semiconductor device 100 illustrated in FIGS. 2 to 4.

In FIG. 12A, a drift layer 102 may be formed on the substrate 101, and a well region 105 and a source region 107 may be formed. The substrate 101 may be provided as a SiC wafer, for example. The drift layer 102 may be formed by epitaxial growth from the substrate 101. The drift layer 102 may include first conductivity-type impurities.

The well region 105 and the source region 107 may be sequentially formed in the drift layer 102 by an ion implantation process. In some implementations, the well contact area 109 may be formed in the well area 105. The well contact region 109 may be formed at a certain depth from one area of the upper surface of the well region 105 before forming the source region 107. Depending on the depth of the well contact area, the contact area with the source electrode (particularly, the contact via) to be formed in a subsequent process may be defined.

Second conductivity-type impurities may be implanted into the well region 105, and first conductivity-type impurities may be implanted into the source region 107. After the ion implantation process, an annealing process may be performed at a high temperature (for example, about 1600° C. to about 1800° C.). The concentration of second conductivity-type impurities in the well contact region 109 may be higher than the concentration of second conductivity-type impurities in the well region 105.

Next, in FIG. 12B, a trench region T may be formed by partially removing the source region 107 and the well region 105. A trench region T may be formed by partially removing the source regions 107 and well regions 105 using a mask layer. The mask layer may be a hard mask, and the process may be performed by anisotropic etching. The sides of the well region 105 may be exposed through the inner sidewalls of the trench region T formed in this process. The trench area T may have a depth extending to a portion of the drift layer 102.

Each of the stacks (ST) patterned by this process may have a pillar structure with rounded sides, with a source region (107) and a well region (105) and some regions of the drift layer (102) as explained in FIGS. 2 and 3. In some implementations, each of the stacks ST may have a cylindrical structure. The trench region T may each have a structure surrounding the stacks ST to define a side surface of the stacks ST.

Next, in FIG. 12C, the gate insulating layer 121 may be formed on the inner surface of the trench region T. In some implementations, after removing the mask layer and before forming the gate insulating layer 121, an annealing process may be performed for surface treatment, and for example, may include a hydrogen (H2) annealing process and a high temperature annealing process performed in a hydrogen (H2) atmosphere. The gate insulating layer 121 may be formed by, for example, an oxidation process, such as a thermal oxidation process. In some embodiments, the gate insulating layer 121 may be formed conformally by a deposition process.

Next, in FIG. 12D, a bottom insulating portion 125 having a top surface at a constant level may be formed on the bottom surfaces of the trench region T. An insulating material may be additionally formed within the trench region (T). The insulating material for the bottom insulating portion 125 may be formed, for example, through a spin-on glass (SOG) process or a high temperature oxide (HTO) process. Next, the insulating material may be etch-backed to form a bottom insulating portion 125 with an adjusted top level (La). Through the etch-back process, the bottom insulating portion 125 may have a top surface with a level (La) that is lower than the bottom level (L1) of the well region 105 by a predetermined distance (d1). The upper surface of the final bottom insulating portion 125 may define the lower surface of the gate electrode (‘130’ in FIG. 12E). During this etch-back process, portions of the gate insulating layer 121 on the source region 107 may also be removed. In some embodiments (for example, see FIGS. 5 and 6), this process may be omitted.

Next, in FIG. 12E, the gate electrode 130 may be formed in the trench region tT where the gate insulating layer 121 and the bottom insulating portion 125 are formed. The gate electrode 130 may be formed, for example, by depositing doped polycrystalline silicon and performing an etch-back process. The gate electrode 130 may be formed to be located only within the trench region (T). In some implementations, through the etch-back process, the gate electrode 130 may have a top surface level lower than the top surface level of the source region 107 by a predetermined distance d2. However, the top surface of the gate electrode 130 may have a level higher than the top surface level of the well region 105 (see FIG. 4).

Next, in FIG. 12F, after forming the interlayer insulating layer 140 covering the gate electrode 130, a first opening O1 exposing the source region 107 of each stack ST may be formed. After the interlayer insulating layer 140 is deposited on the entire upper surface of the result of FIG. 12E, a first opening O1 is formed to open a portion of each of the source regions 107 through an etching process using a mask. In some implementations, when the gate insulating layer 121 remains on the source regions 107, the remaining gate insulating layer 121 may be patterned together during the patterning process of the interlayer insulating layer.

Next, in FIG. 12G, contact holes may be formed in each stack s using the photoresist pattern PR1 having the second opening O2. The second opening O2 may expose a portion of each stacks to the source regions 105 opened by the first opening O1, and have a contact hole extending from the top surface of the source regions 107 to the well regions 105 through an etching process using the photoresist pattern PR1. Not only the source region 107 but also a partial region of the well region 105 may be exposed through the inner sidewall of the contact hole. In some implementations, the well contact area 109 located within the well area 105 may be exposed.

Next, in FIG. 12H, after removing the photoresist pattern PR1, metal-semiconductor compound layers 152 may be formed, and an electrode layer 154 may be formed on the metal-semiconductor compound layers 152. The metal-semiconductor compound layers 152 may be formed on the open top regions of the source regions 107 and surfaces of the source regions 107 and well regions 105 that are open on the inner sidewalls of the contact holes. The metal-semiconductor compound layers 152 may be formed, for example, through a silicidation process. The electrode layer 154 may be formed to cover the metal-semiconductor compound layers 152 and the interlayer insulating layer 140. In this process, the electrode layer 152 may have contact vias 154V extending into the contact hole. The source electrode 150 contacts the well region through the contact vias 154V, so that the power semiconductor device may improve robustness and current capability. In some implementations, the contact vias are described as part of the electrode layer, but they may be understood as a structure corresponding to a conductive material extending into the contact hole. Accordingly, the contact via 154V may include metal-semiconductor compound layers 152 located within the contact hole, and when the contact hole is almost filled by the metal-semiconductor compound layers 152, the contact via 154V may be composed almost exclusively of the metal-semiconductor compound layers 152.

Next, as shown in FIG. 3, a drain electrode 160 may be formed on the lower surface of the substrate 101. In detail, the drain electrode 160 may be formed by depositing a metal material on the lower surface of the substrate 101. In some implementations, drain electrode 160 may be formed in another process step. Through these processes, the power semiconductor device 100 illustrated in FIGS. 1 to 4 may be manufactured.

FIGS. 13A to 13G are cross-sectional views for examples of main processes of an example of a method of manufacturing a power semiconductor device according to some implementations. The manufacturing method may be understood as the method of manufacturing the power semiconductor device 100C illustrated in FIGS. 9 and 10.

In FIG. 13A, a trench region T may be formed by partially removing the source region 107 and the well region 105. This process may be understood as the result of the processes illustrated in FIGS. 12A and 12B in some implementations.

However, the formation area of the well contact areas 109B is different from some implementations. In some implementations, the well contact regions 109B are provided only in the first stack ST1 and may be formed to contact the well region 105 from the top surface of the first source region 107A. The well contact region 109B may include a semiconductor material, for example, SiC. The well contact region 109B may be a region having the second conductivity-type, and may include the second conductivity-type impurities described above. The concentration of second conductivity-type impurities in the well contact region 109B may be higher than the concentration of second conductivity-type impurities in the well region 105.

A trench region T may be formed by partially removing the source regions 107 and well regions 105 using a mask layer. The sides of the well region 105 may be exposed through the inner sidewalls of the trench region T formed in this process. The trench area T may have a depth extending to a portion of the drift layer 102.

Each of the stacks (ST) patterned by this process may have a pillar structure with rounded sides (for example, a circular pillar structure), together with the source region 107 and well region 105 and some regions of the drift layer 102.

Next, in FIG. 13B, a photoresist pattern PR2 is formed to expose the second stacks ST2, and an ion implantation process for counter doping is performed.

A photoresist pattern PR2 is formed on the result illustrated in FIG. 13A to cover the first stacks ST1 and the trench region T and to open the second stacks ST2. This counter doping includes a process of injecting a second conductivity-type impurity at a high concentration. By this counter doping process, the first source region 107A of the first stacks ST1 is maintained as the first conductivity-type, and the second source region 107B of the second stacks ST2 may be converted from the first conductivity-type to the second conductivity-type.

Next, in FIG. 13C, the gate insulating layer 121 may be formed on the inner surface of the trench region T. The gate insulating layer 121 may be formed through, for example, an oxidation process, such as a thermal oxidation process. In some implementations, the gate insulating layer 121 may be formed conformally by a deposition process.

Next, in FIG. 13D, a bottom insulating portion 125 having an upper surface at a constant level is formed on the bottom surfaces of the trench region T (see the process of FIG. 12D), and a gate electrode 130 is formed on the bottom insulating portion in the trench region T (see the process in FIG. 12E). Next, after forming the interlayer insulating layer 140 covering the gate electrode 130, an opening exposing the source region 107 of each stack ST may be formed (see the process in FIG. 12F). This series of processes may be understood with reference to the processes described in FIGS. 12D to 12G.

Next, in FIG. 13E, after forming the interlayer insulating layer 140 covering the gate electrode 130, an opening O3 exposing the source region 107 of each stack ST is formed. (see process in FIG. 12f). This series of processes may be understood with reference to the processes described in FIGS. 12D to 12G.

Next, in FIG. 13F, metal-semiconductor compound layers 152 are formed in the exposed first and second source regions 107A and 107B of the opening. In this manner, the metal semiconductor compound layers 152 may be formed on the open upper surfaces of the first and second source regions 107A and 107B.

Next, in FIG. 13G, the desired source electrode 150 may be formed by forming an electrode layer 154 connected to the metal-semiconductor compound layers 152 on the interlayer insulating layer 140. Next, referring to FIG. 10, the power semiconductor device 100C may be manufactured by forming the drain electrode 160 on the lower surface of the substrate 101. The source electrode 150 contacts the source regions 107A of the second conductivity-type instead of the well region, so that the power semiconductor device may improve robustness and current capability.

As set forth above, a channel region surrounding the sides of the well region may be provided by forming a second conductive well region with the first conductivity-type source region thereabove in a pattern of a plurality of pillar structures with rounded sides (Gate All Around structure). As a result, not only may mobility be improved, but the channel region may be significantly increased.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A power semiconductor device comprising:
a substrate of a first conductivity-type;
a drift layer of the first conductivity-type on a first side of the substrate;
a plurality of well regions of a second conductivity-type on the drift layer, the plurality of well regions arranged at an interval;
a plurality of source regions of the first conductivity-type respectively disposed on the plurality of well regions to thereby define stacks of the plurality of well regions and the plurality of source regions, each of the stacks having rounded sides;
a gate electrode surrounding the stacks and filling a space between the stacks;
a gate insulating layer disposed between the stacks and the gate electrode;
an interlayer insulating layer on the gate electrode;
a source electrode disposed on the interlayer insulating layer and having a plurality of contact vias respectively extending from upper surfaces of the plurality of source regions to the plurality of well regions; and
a drain electrode on a second side of the substrate opposite to the first side of the substrate.

2. The power semiconductor device of claim 1, wherein each of the stacks has a circular shape.

3. The power semiconductor device of claim 2, wherein the stacks are arranged in a hexagonal shape.

4. The power semiconductor device of claim 2, wherein the stacks are arranged in a square shape.

5. The power semiconductor device of claim 2, wherein a diameter of each of the stacks is 0.3 to 1.5 times the interval.

6. The power semiconductor device of claim 1, wherein a lower surface of the gate electrode is located at a lower level than lower surfaces of the well regions.

7. The power semiconductor device of claim 1, wherein an upper surface of the gate electrode is located at a higher level than lower surfaces of the source regions.

8. The power semiconductor device of claim 7, wherein the upper surface of the gate electrode is located at a lower level than the lower surfaces of the source regions.

9. The power semiconductor device of claim 1, further comprising a bottom insulating portion connected to the gate insulating layer and extending to a bottom of the gate electrode.

10. The power semiconductor device of claim 9, wherein the bottom insulating portion has a thickness greater than a thickness of the gate insulating layer.

11. The power semiconductor device of claim 1, wherein the source electrode further comprises a plurality of metal-semiconductor compound layers respectively extending from the upper surface of the plurality of source regions to the plurality of well regions.

12. The power semiconductor device of claim 1, wherein the substrate comprises a SiC substrate, and the drift layer comprises a SiC epitaxial layer.

13. A power semiconductor device comprising:
a substrate of a first conductivity-type;
a drift layer of the first conductivity-type on a first surface of the substrate;
a plurality of well regions of a second conductivity-type arranged at an interval on the drift layer, the plurality of well regions including first well regions and second well regions;
first source regions of the first conductivity-type respectively disposed on the first well regions to thereby define first stacks of the first well regions and the first source regions, each of the first stacks having a first rounded side surface;
second source regions of the second conductivity-type respectively disposed on the second well regions to thereby define second stacks of the second well regions and the second source regions, each of the second stacks having a second rounded side surface;
a gate electrode surrounding each of the first stack and the second stack and filling a space between the first stack and the second stack;
a gate insulating layer disposed between the first stacks and the gate electrode;
an interlayer insulating layer on the gate electrode;
a source electrode disposed on the interlayer insulating layer and connected to the first source region and the second source region; and
a drain electrode on a second surface of the substrate opposite to the first surface of the substrate.

14. The power semiconductor device of claim 13, wherein each of the first and second stacks has a circular shape.

15. The power semiconductor device of claim 14, wherein the first and second stacks are arranged in a hexagonal shape.

16. The power semiconductor device of claim 14, wherein a diameter of each of the first and second stacks is 0.5 to 1.5 times the interval.

17. The power semiconductor device of claim 13, wherein the gate electrode has a lower surface lower than lower surfaces of the first well regions and the second well regions and an upper surface higher than lower surfaces of the first source region and the second source region.

18. The power semiconductor device of claim 13, further comprising a bottom insulating portion connected to the gate insulating layer and extending to a bottom of the gate electrode, wherein the bottom insulating portion has a thickness greater than a thickness of the gate insulating layer.

19. A power semiconductor device comprising:
a substrate of a first conductivity-type;
a drift layer of the first conductivity-type on a first surface of the substrate;
a plurality of well regions of a second conductivity-type on the drift layer and arranged in a hexagonal shape;
a plurality of source regions of the first conductivity-type respectively disposed on the plurality of well regions to thereby define stacks of the plurality of well regions and the plurality of source regions, each of the stacks having a cylindrical structure;
gate electrodes filled in trenches defining the stacks;
a gate insulating layer disposed between the stacks and the gate electrode, and surrounding the stacks;
an interlayer insulating layer on the gate electrode;
a source electrode disposed on the interlayer insulating layer and having a plurality of contact vias extending from upper surfaces of the plurality of source regions to the plurality of well regions; and
a drain electrode on a second surface of the substrate opposite to the first surface of the substrate.

20. The power semiconductor device of claim 19, wherein the trench extends to a portion of the drift layer at a location lower than lower surfaces of the plurality of well regions.

21.-26. (canceled)
